(19) United States
(12) Patent Application Publication
(10) Pub. No.: US 2026/0293100 A1
(43) Pub. Date: Sep. 24, 2026

(54) SEMICONDUCTOR DEVICE AND METHOD OF MANUFACTURING SAME

(71) Applicant: Kioxia Corporation, Tokyo (JP)

(72) Inventor: Yasuyuki SONODA, Yokkaichi Mie (JP)

(73) Assignee: Kioxia Corporation, Tokyo (JP)

(21) Appl. No.: 19/234,563

(22) Filed: Jun. 11, 2025

(30) Foreign Application Priority Data
Mar. 18, 2025 (JP) 2025-043838

(51) Int. Cl. H10B 12/00; H01L 23/00

(52) U.S. Cl. CPC H10B 12/33; H10B 12/05; H10W 72/923; H10W 72/942

(57) ABSTRACT

In one embodiment, a semiconductor device includes an oxide semiconductor layer including a metal element and oxygen, the oxide semiconductor layer being a channel of a transistor. The device further includes a first film provided above the oxide semiconductor layer, and including silicon and nitrogen. The device further includes a hydrogen storage layer provided between the oxide semiconductor layer and the first film.

### CROSS REFERENCE TO RELATED APPLICATION

This application is based upon and claims the benefit of priority from the prior Japanese Patent Application No. 2025-043838, filed on Mar. 18, 2025, the entire contents of which are incorporated herein by reference.

### FIELD

Embodiments described herein relate to a semiconductor device and a method of manufacturing the same.

### BACKGROUND

When hydrogen radicals reach a semiconductor layer such as an IGZO layer, the characteristics of the semiconductor layer are changed to potentially degrade the performance of a transistor including the semiconductor layer. The hydrogen radicals are generated, for example, when a silicon nitride film is formed by using source gas including hydrogen (H).

### BRIEF DESCRIPTION OF THE DRAWINGS

FIG. 1 is a circuit diagram illustrating the configuration of a semiconductor device of a first embodiment;

FIG. 2 is a cross-sectional view illustrating the structure of the semiconductor device of the first embodiment;

FIGS. 3 to 6 are cross-sectional views illustrating a method of manufacturing the semiconductor device of the first embodiment;

FIG. 7 is a cross-sectional view illustrating the structure of the semiconductor device of the first embodiment;

FIGS. 8 to 10 are cross-sectional views illustrating the method of manufacturing the semiconductor device of the first embodiment;

FIGS. 11A and 11B are cross-sectional views illustrating the structure of the semiconductor device of the first embodiment and the structure of a semiconductor device of a comparative example of the first embodiment;

FIGS. 12A to 13B are cross-sectional views illustrating the method of manufacturing the semiconductor device of the first embodiment;

FIG. 14 is a cross-sectional view illustrating the structure of a semiconductor device of a second embodiment; and

FIG. 15 is a cross-sectional view illustrating a method of manufacturing the semiconductor device of the second embodiment.

### DETAILED DESCRIPTION

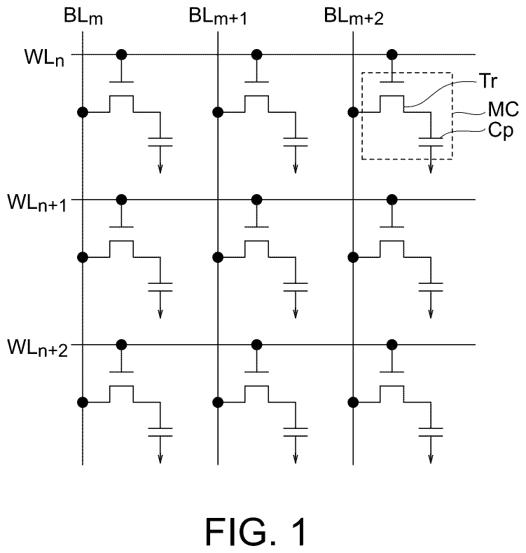

Embodiments will now be explained with reference to the accompanying drawings. In FIGS. 1 to 15, identical components are denoted by the same reference sign, and duplicate description thereof is omitted.

In one embodiment, a semiconductor device includes an oxide semiconductor layer including a metal element and oxygen, the oxide semiconductor layer being a channel of a transistor. The device further includes a first film provided above the oxide semiconductor layer, and including silicon and nitrogen. The device further includes a hydrogen storage layer provided between the oxide semiconductor layer and the first film.

### First Embodiment

FIG. 1 is a circuit diagram illustrating the configuration of a semiconductor device of a first embodiment. The semiconductor device of the present embodiment is, for example, a dynamic random access memory (DRAM).

The semiconductor device of the present embodiment includes a plurality of word lines WL extending in a row direction, a plurality of bit lines BL extending in a column direction, and a plurality of memory cells MC disposed in a two-dimensional array. FIG. 1 illustrates three word lines WLₙ, WLₙ₊₁, and WLₙ₊₂ (n is an integer of two or greater) as examples of the plurality of word lines WL. FIG. 1 further illustrates three bit lines BLₘ, BLₘ₊₁, and BLₘ₊₂ (m is an integer of two or greater) as examples of the plurality of bit lines BL.

Each memory cell MC includes a transistor Tr and a capacitor Cp and is disposed near an intersection point of one word line WL and one bit line BL. The gate of the transistor Tr is electrically connected to the word line WL, one of the source and drain of the transistor Tr is electrically connected to the bit line BL, and the other of the source and drain of the transistor Tr is electrically connected to the capacitor Cp. One of the electrodes of the capacitor Cp is electrically connected to the transistor Tr, and the other electrode of the capacitor Cp is electrically connected to a ground line.

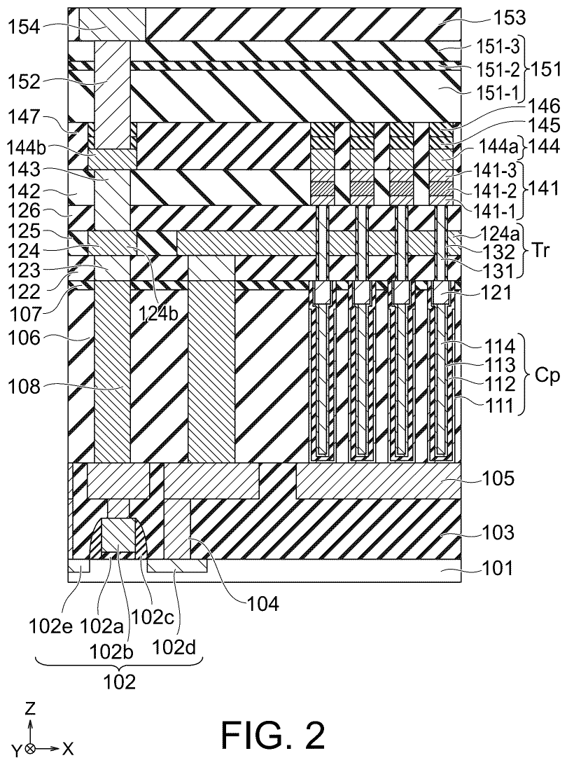

FIG. 2 is a cross-sectional view illustrating the structure of the semiconductor device of the first embodiment. FIG. 2 illustrates, as an example, a section of four transistors Tr and four capacitors Cp constituting four memory cells MC.

The semiconductor device of the present embodiment includes a substrate 101, a transistor 102, an interlayer dielectric 103, a plurality of contact plugs 104, an interconnect layer 105, an interlayer dielectric 106, an interlayer dielectric 107, and a plurality of via plugs 108. The transistor 102 includes a gate insulator 102a, a gate electrode 102b, a sidewall insulator 102c, a diffusion region 102d, and a diffusion region 102e.

The substrate 101 is, for example, a semiconductor substrate such as a silicon (Si) substrate. FIG. 2 illustrates an X direction and a Y direction that are parallel to a surface of the substrate 101 and orthogonal to each other, and a Z direction that is orthogonal to the surface of the substrate 101. In the present specification, the positive Z direction is treated as an upward direction, and the negative Z direction is treated as a downward direction. The negative Z direction may be or may not be aligned with the direction of gravity.

The transistor 102 is formed on the substrate 101. Specifically, the gate insulator 102a and the gate electrode 102b are sequentially formed on the substrate 101, and the sidewall insulator 102c is formed on the side face of the gate electrode 102b. The diffusion regions 102d and 102e are formed in the substrate 101 so as to sandwich the gate electrode 102b and each function as a source or drain region of the transistor 102. The semiconductor device of the present embodiment includes a plurality of transistors 102, one of which is illustrated in FIG. 2. These transistors 102 constitute, for example, a peripheral circuit of a DRAM.

The interlayer dielectric 103 is formed on the substrate 101 to cover the transistors 102. Each contact plug 104 is formed on the gate electrode 102b, the diffusion region 102d, or the diffusion region 102e in the interlayer dielectric 103. The interconnect layer 105 is formed on each contact plug 104 in the interlayer dielectric 103. FIG. 2 illustrates a plurality of interconnects included in the interconnect layer 105.

The interlayer dielectric 106 is formed on the interlayer dielectric 103 and the interconnect layer 105. The interlayer dielectric 107 is formed on the interlayer dielectric 106. Each via plug 108 is formed on the interconnect layer 105 in the interlayer dielectrics 106 and 107. In FIG. 2, each via plug 108 penetrates through the interlayer dielectrics 106 and 107.

Each capacitor Cp of the present embodiment includes a conductive layer 111, a dielectric layer 112, a conductive layer 113, and a conductive layer 114.

The conductive layer 111, the dielectric layer 112, the conductive layer 113, and the conductive layer 114 are sequentially formed on the side and bottom faces of a concave portion formed in the interlayer dielectrics 106 and 107. Specifically, the conductive layer 111 is formed on the side faces of the interlayer dielectrics 106 and 107 and the upper face of the interconnect layer 105 in the concave portion. The conductive layer 111 functions as one of the electrodes of each capacitor Cp, and the conductive layers 113 and 114 function as the other electrode of the capacitor Cp. The conductive layers 111, 113, and 114 are each, for example, a semiconductor layer or a metal layer. The dielectric layer 112 is, for example, a silicon oxide film (SiO₂ film).

The semiconductor device of the present embodiment further includes a conductive layer 121, an interlayer dielectric 122, a plurality of via plugs 123, an interconnect layer 124, an interlayer dielectric 125, and an interlayer dielectric 126. The interconnect layer 124 includes an interconnect 124a and an interconnect 124b.

The conductive layer 121 includes a plurality of conductive layer portions disposed on the plurality of capacitors Cp. In FIG. 2, the conductive layer 121 includes four conductive layer portions, and each conductive layer portion is disposed on the conductive layers 113 and 114 of the corresponding one capacitor Cp. Each conductive layer portion is disposed in a concave portion for the corresponding one capacitor Cp and disposed below the corresponding one transistor Tr. Each conductive layer portion functions as a source electrode or drain electrode of the corresponding one transistor Tr.

The conductive layer 121 is, for example, an oxide conductive layer. The oxide conductive layer includes, for example, a metal element and oxygen. Examples of the oxide conductive layer include an InO-based conductive layer, a ZnO-based conductive layer, and a TiO-based conductive layer (where In denotes indium, O denotes oxygen, Zn denotes zinc, and Ti denotes titanium). The conductive layer 121 of the present embodiment is, for example, an indium tin oxide (ITO) layer including In, tin (Sn), and O. The conductive layer 121 may include O and at least one element selected from the group consisting of In, gallium (Ga), Zn, Sn, Ti, tantalum (Ta), tungsten (W), molybdenum (Mo), aluminum (Al), magnesium (Mg), calcium (Ca), and manganese (Mn).

The interlayer dielectric 122 is formed on the interlayer dielectric 107 to cover the capacitors Cp. Each via plug 123 is formed on the corresponding one via plug 108 in the interlayer dielectric 122. The interconnect layer 124 and the interlayer dielectric 125 are formed on the interlayer dielectric 122. The interconnect 124a in the interconnect layer 124 is disposed on the corresponding one via plug 123, and the interconnect 124b in the interconnect layer 124 is disposed on the corresponding one via plug 123 as well. The interconnect 124a functions as the gate electrode of each transistor Tr illustrated in FIG. 2. The interlayer dielectric 126 is formed on the interconnect layer 124 and the interlayer dielectric 125. The interlayer dielectrics 122, 125, and 126 are, for example, SiO₂ films. The interconnect layer 124 is, for example, a metal layer such as a W layer.

Each transistor Tr of the present embodiment includes a semiconductor layer 131 and an insulator 132. Each transistor Tr of the present embodiment further includes the interconnect 124a in the interconnect layer 124 as a constituent component of the transistor Tr.

The semiconductor layer 131 is formed in a concave portion formed in the interlayer dielectric 122, the interconnect layer 124 (interconnect 124a) and the interlayer dielectric 126 via the insulator 132. In FIG. 2, the semiconductor layer 131 is formed on one conductive layer portion of the conductive layer 121 and contacts the conductive layer portion. Accordingly, the semiconductor layer 131 of each transistor Tr is electrically connected to the conductive layers 113 and 114 of the corresponding one capacitor Cp. The semiconductor layer 131 functions as a channel semiconductor layer of each transistor Tr. The semiconductor layer 131 is, for example, an oxide semiconductor layer. The oxide semiconductor layer includes, for example, a metal element and oxygen. The semiconductor layer 131 of the present embodiment is, for example, an IGZO layer including In, Ga, Zn, and O. The semiconductor layer 131 may include In, O, and at least one element selected from the group consisting of Ga, Zn, Sn, Al, and Si.

The insulator 132 is formed on the side face of a concave portion formed in the interlayer dielectric 122, the interconnect layer 124, and the interlayer dielectric 126 and formed on the side face of the semiconductor layer 131 in the concave portion. The insulator 132 functions as a gate insulator of each transistor Tr. The insulator 132 is, for example, a stacked film including a SiO₂ film and a silicon nitride film (SiN film).

In FIG. 2, the insulator 132 and the semiconductor layer 131 of each transistor Tr are sequentially formed on the side face of the interconnect 124a. As described above, the interconnect 124a functions as the gate electrode of each transistor Tr. The interconnect 124a illustrated in FIG. 2 extends in the X direction and functions as one word line WL for the four transistors Tr illustrated in FIG. 2. The interconnect 124a is electrically connected to the diffusion region 102d of each transistor 102 through the via plugs 123 and 108 and the like.

The semiconductor device of the present embodiment further includes a plurality of conductive pads 141, an interlayer dielectric 142, a via plug 143, an interconnect layer 144, an insulator 145, an insulator 146, and an interlayer dielectric 147. Each conductive pad 141 includes a conductive layer 141-1, a conductive layer 141-2, and a conductive layer 141-3. The interconnect layer 144 further includes a plurality of interconnects 144a and an interconnect 144b.

Each conductive pad 141 is formed on the semiconductor layer 131 of the corresponding one transistor Tr in the interlayer dielectric 142 and contacts the semiconductor layer 131. Specifically, the conductive layers 141-1, 141-2, and 141-3 in each conductive pad 141 are sequentially formed on the semiconductor layer 131. Each conductive pad 141 functions as a source electrode or drain electrode of the corresponding one transistor Tr.

The conductive layer 141-1 is, for example, an oxide conductive layer. The oxide conductive layer includes, for example, a metal element and oxygen. Examples of the oxide conductive layer include an InO-based conductive layer, a ZnO-based conductive layer, and a TiO-based conductive layer. The conductive layer 141-1 of the present embodiment is, for example, an ITO layer including In, Sn, and O. The conductive layer 141-1 may include O and at least one element selected from the group consisting of In, Ga, Zn, Sn, Ti, Ta, W, Mo, Al, Mg, Ca, and Mn. The conductive layer 141-2 is, for example, a TiN layer. The conductive layer 141-3 is, for example, a W layer.

The interlayer dielectric 142 is formed on the interlayer dielectric 126. The via plug 143 is formed on the interconnect 124b in the interlayer dielectrics 126 and 142. Note that the interconnect 124b is electrically connected to the electrode 102b of each transistor 102 through the via plugs 123 and 108 and the like.

The interconnect layer 144, the insulator 145, and the insulator 146 are formed in the interlayer dielectric 147. In FIG. 2, each interconnect 144a in the interconnect layer 144 is formed on the corresponding one conductive pad 141. The four interconnects 144a illustrated in FIG. 2 extend in the Y direction and function as four bit lines BL for the four transistors Tr illustrated in FIG. 2. The interconnect 144b in the interconnect layer 144 is formed on the via plug 143. The interconnect layer 144 is, for example, a metal layer such as a W layer.

The insulator 145 is divided into a plurality of insulator portions, and each insulator portion in the insulator 145 is formed on one interconnect 144a or the interconnect 144b. The insulator 145 is, for example, an SiO₂ film. The insulator 146 is divided into a plurality of insulator portions, and each insulator portion in the insulator 146 is formed on one insulator portion in the insulator 145. The insulator 146 is, for example, a SiN film. The interlayer dielectric 147 is formed on the interlayer dielectric 142.

The semiconductor device of the present embodiment further includes an interlayer dielectric 151, a via plug 152, an interlayer dielectric 153, and an interconnect layer 154. The interlayer dielectric 151 includes a SiO₂ film 151-1, a SiN film 151-2, and a SiO₂ film 151-3 as insulators.

The interlayer dielectric 151 is formed on the insulator 146 and the interlayer dielectric 147. Specifically, the SiO₂ film 151-1 is formed on the insulator 146 and the interlayer dielectric 147, the SiN film 151-2 is formed on the SiO₂ film 151-1, and the SiO₂ film 151-3 is formed on the SiN film 151-2. Note that the insulators included in the interlayer dielectric 151 may be insulators other than the SiO₂ film 151-1, the SiN film 151-2, and the SiO₂ film 151-3.

The via plug 152 is formed on the interconnect 144b in the interlayer dielectric 151, the insulator 146, and the insulator 145. The interlayer dielectric 153 is formed on the interlayer dielectric 151. The interconnect layer 154 is formed on the via plug 152 in the interlayer dielectric 153.

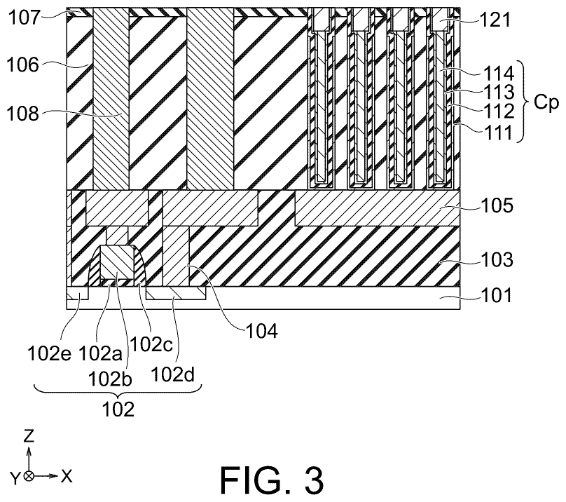

FIGS. 3 to 6 are cross-sectional views illustrating a method of manufacturing the semiconductor device of the first embodiment.

First, each transistor 102 is formed on the substrate 101 (FIG. 3). Specifically, the diffusion regions 102d and 102e are formed in the substrate 101, and the gate insulator 102a, the gate electrode 102b, and the sidewall insulator 102c are formed on the substrate 101.

Subsequently, the interlayer dielectric 103, the plurality of contact plugs 104, and the interconnect layer 105 are formed on the substrate 101 and the transistor 102 (FIG. 3). Subsequently, the interlayer dielectric 106, the interlayer dielectric 107, and the plurality of via plugs 108 are formed on the interlayer dielectric 103 and the interconnect layer 105 (FIG. 3).

Subsequently, a plurality of concave portions are formed in the interlayer dielectrics 106 and 107, and the plurality of capacitors Cp and formed in these concave portions (FIG. 3). Each capacitor Cp is formed by sequentially forming the conductive layer 111, the dielectric layer 112, the conductive layer 113, and the conductive layer 114 in one concave portion. The conductive layer 111 is formed on the interconnect layer 105 in the concave portion. Thereafter, the plurality of conductive layer portions of the conductive layer 121 are formed in the above-described plurality of concave portions, as well. Each conductive layer portion is formed on the conductive layers 113 and 114 in one concave portion.

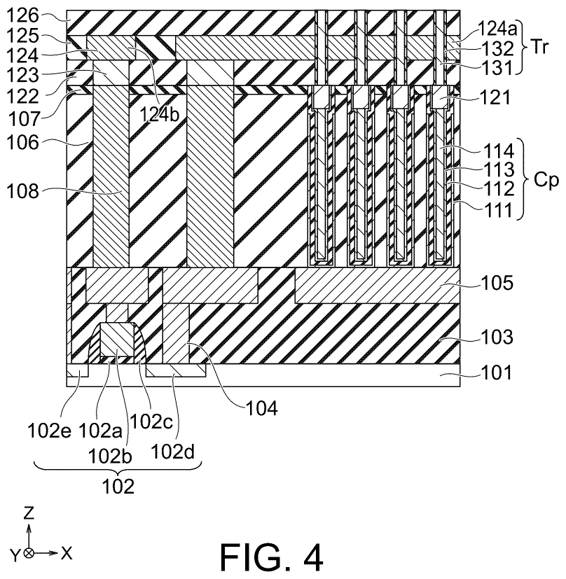

Subsequently, the interlayer dielectric 122 and the plurality of via plugs 123 are formed on the interlayer dielectric 107, the plurality of via plugs 108, and the conductive layer 121 (FIG. 4). Subsequently, the interconnect layer 124 and the interlayer dielectric 125 are formed on the interlayer dielectric 122 and the plurality of via plugs 123 (FIG. 4). The interconnect layer 124 is formed so as to include the interconnects 124a and 124b. Subsequently, the interlayer dielectric 126 is formed on the interconnect layer 124 and the interlayer dielectric 125 (FIG. 4).

Subsequently, the plurality of transistors Tr are formed in the interlayer dielectric 122, the interconnect layer 124 (interconnect 124a), and the interlayer dielectric 126 (FIG. 4). Specifically, a plurality of concave portions are formed in the interlayer dielectric 122, the interconnect layer 124, and the interlayer dielectric 126, and the insulator 132 and the semiconductor layer 131 are sequentially formed in each concave portion. Accordingly, each transistor Tr is formed so as to include the semiconductor layer 131, the insulator 132, and the interconnect 124a. The semiconductor layer 131 of each transistor Tr is formed on one conductive layer portion of the conductive layer 121. As a result, the semiconductor layer 131 of each transistor Tr is electrically connected to the conductive layers 113 and 114 of the corresponding one capacitor Cp.

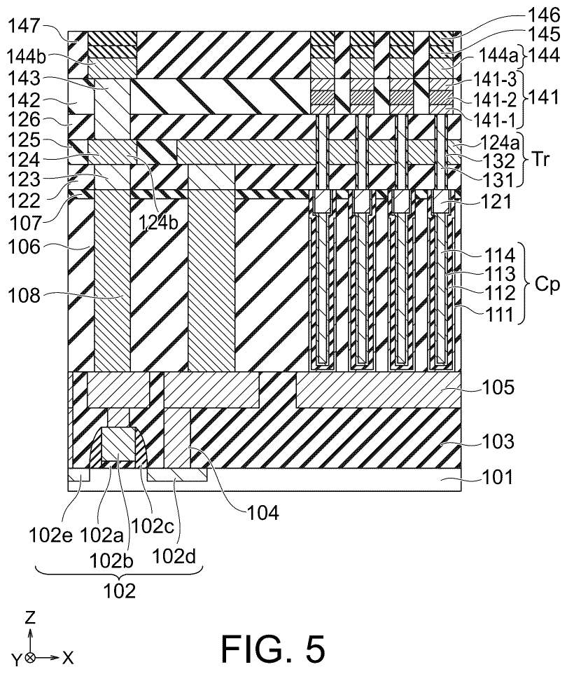

Subsequently, the plurality of conductive pads 141 and the interlayer dielectric 142 are formed on the interlayer dielectric 122 and the plurality of transistors Tr, and the via plug 143 is formed in the interlayer dielectrics 142 and 126 (FIG. 5). Each conductive pad 141 is formed so as to include the conductive layers 141-1, 141-2, and 141-3 sequentially formed on the semiconductor layer 131 of the corresponding one transistor Tr. The via plug 143 is formed on the interconnect 124b of the interconnect layer 124.

Subsequently, the interconnect layer 144, the insulator 145, the insulator 146, and the interlayer dielectric 147 are formed on the plurality of conductive pads 141, the interlayer dielectric 142, and the via plug 143 (FIG. 5). The interconnect layer 144 is formed so as to include the plurality of interconnects 144a on the plurality of conductive pads 141, and the interconnect 144b on the via plug 143. The insulators 145 and 146 are sequentially formed on the interconnect layer 144. Similarly to the interconnects 144a and 144b in the interconnect layer 144, the insulators 145 and 146 are each divided into a plurality of insulator portions.

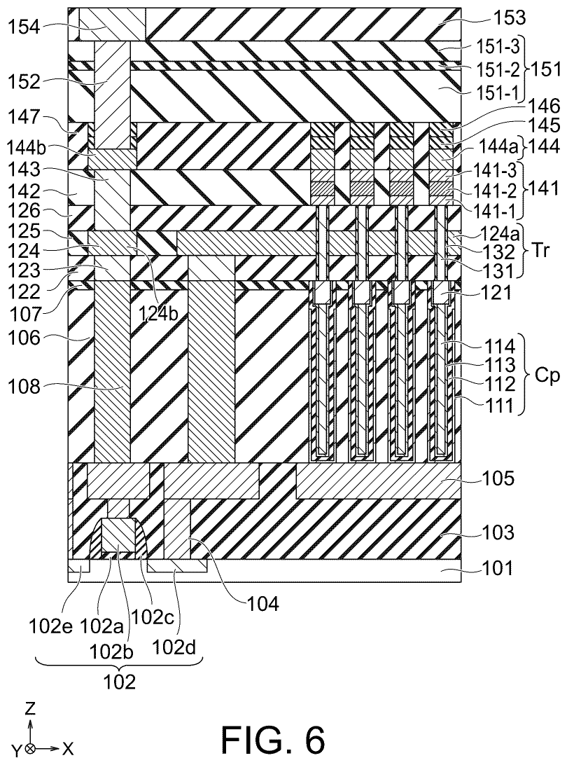

Subsequently, the interlayer dielectric 151 is formed on the insulator 146 and the interlayer dielectric 147, and the via plug 152 are formed in the interlayer dielectric 151, the insulator 146, and the insulator 145 (FIG. 6). The interlayer dielectric 151 is formed so as to include the SiO₂ film 151-1, the SiN film 151-2, and the SiO₂ film 151-3 sequentially formed on the insulator 146 and the interlayer dielectric 147. The via plug 152 is formed on the interconnect 144b.

Subsequently, the interlayer dielectric 153 and the interconnect layer 154 are formed on the interlayer dielectric 151 and the via plug 152 (FIG. 6). The interconnect layer 154 is formed on the via plug 152. In this manner, the semiconductor device of the present embodiment is manufactured.

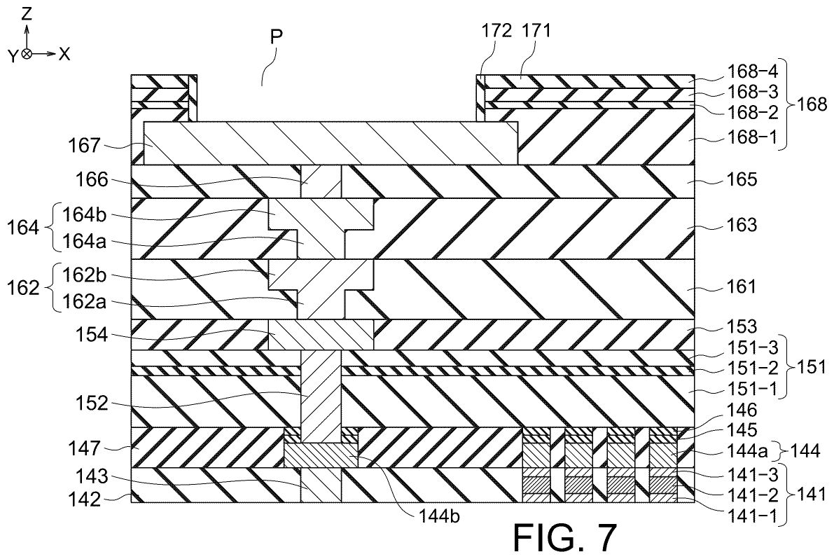

FIG. 7 is a cross-sectional view illustrating the structure of the semiconductor device of the first embodiment. FIGS. 2 and 7 illustrate different portions of the same semiconductor device. Specifically, the portion illustrated in FIG. 7 is positioned above the portion illustrated in FIG. 2.

The semiconductor device of the present embodiment includes an interlayer dielectric 161, an interconnect layer 162, an interlayer dielectric 163, an interconnect layer 164, an interlayer dielectric 165, a via plug 166, a bonding pad 167, and a passivation insulator 168 in addition to the components illustrated in FIG. 2 element. The passivation insulator 168 is an example of a first insulator.

The interconnect layer 162 includes a via plug portion 162a and an interconnect portion 162b. The interconnect layer 164 includes a via plug portion 164a and an interconnect portion 164b. The passivation insulator 168 includes a SiO₂ film 168-1, a hydrogen storage layer 168-2, a SiN film 168-3, and a polyimide film 168-4 as insulators. The polyimide film 168-4 includes a polyimide film 171 and a polyimide film 172. The hydrogen storage layer 168-2 is an example of a first layer. The SiN film 168-3 is an example of a first film. The polyimide film 168-4 is an example of a second film and an example of an organic insulator.

The interlayer dielectric 161 is formed on the interlayer dielectric 153 and the interconnect layer 154. The interlayer dielectric 161 is, for example, an SiO₂ film. The interconnect layer 162 is formed in the interlayer dielectric 161. FIG. 7 illustrates one interconnect in the interconnect layer 162. The interconnect is, for example, a dual damascene interconnect. The interconnect includes the via plug portion 162a formed on the interconnect layer 154 to function as a via plug, and the interconnect portion 162b formed on the via plug portion 162a to function as an interconnect. The interconnect layer 162 is, for example, a metal layer including a copper (Cu) layer.

The interlayer dielectric 163 is formed on the interlayer dielectric 161 and the interconnect layer 162. The interlayer dielectric 163 is, for example, an SiO₂ film. The interconnect layer 164 is formed in the interlayer dielectric 163. FIG. 7 illustrates one interconnect in the interconnect layer 164. The interconnect is, for example, a dual damascene interconnect. The interconnect includes the via plug portion 164a formed on the interconnect portion 162b to function as a via plug, and the interconnect portion 164b formed on the via plug portion 164a to function as an interconnect. The interconnect layer 164 is, for example, a metal layer including a Cu layer.

The interlayer dielectric 165 is formed on the interlayer dielectric 163 and the interconnect layer 164. The interlayer dielectric 165 is, for example, an SiO₂ film. The via plug 166 is formed on the interconnect portion 164b in the interlayer dielectric 165. The via plug 166 is, for example, a metal layer including a W layer.

The bonding pad 167 is formed on the interlayer dielectric 165 and the via plug 166. The bonding pad 167 functions as an external connection pad of the semiconductor device of the present embodiment. The bonding pad 167 is, for example, a metal layer including an Al layer. The passivation insulator 168 is formed on the interlayer dielectric 165 and the bonding pad 167 and includes an opening P on the bonding pad 167. The upper face of the bonding pad 167 is exposed in the opening P. The bonding pad 167 is electrically connectable to a mounting substrate or another device with a bonding wire, a soldering ball, a metal bump, or the like through the opening P.

The SiO₂ film 168-1 is formed on the interlayer dielectric 165 and the bonding pad 167. The SiO₂ film 168-1 is, for example, a high density plasma (HDP)-SiO₂ film.

The hydrogen storage layer 168-2 is formed on the SiO₂ film 168-1. The hydrogen storage layer 168-2 is a layer capable of storing hydrogen (H). The hydrogen storage layer 168-2 includes, for example, a metal element. The metal element is, for example, titanium (Ti), tantalum (Ta), hafnium (Hf), lanthanum (La), or zirconium (Zr). The hydrogen storage layer 168-2 includes, for example, a metal element and includes oxygen or nitrogen. Examples of such a hydrogen storage layer 168-2 include a metal oxide film and a metal nitride film. The hydrogen storage layer 168-2 is, for example, an insulator. The thickness of the hydrogen storage layer 168-2 is, for example, 20 to 30 nm. It is possible to enhance the H storage capability of the hydrogen storage layer 168-2 by increasing the thickness of the hydrogen storage layer 168-2, and it is possible to suppress excessive increase in the thickness of the passivation insulator 168 by decreasing the thickness of the hydrogen storage layer 168-2.

The SiN film 168-3 is formed on the hydrogen storage layer 168-2. The density of the SiN film 168-3 is, for example, higher than 2.7 g/cm³ but may be lower than 2.7 g/cm³. The density of the SiN film 168-3 can be adjusted by, for example, changing temperature and source gas for forming the SiN film 168-3. According to the present embodiment, since the SiN film 168-3 is provided in the passivation insulator 168, it is possible to prevent, for example, H₂O molecules (water molecules) in air from entering the semiconductor device.

The SiO₂ film 168-1, the hydrogen storage layer 168-2, and the SiN film 168-3 each have a plate shape spreading along the XY plane above the semiconductor layer 131 (refer to FIG. 2) of each transistor Tr. Accordingly, the semiconductor layer 131 of each transistor Tr of the present embodiment is disposed so as to overlap the SiO₂ film 168-1, the hydrogen storage layer 168-2, and the SiN film 168-3 in a plan view. The hydrogen storage layer 168-2 is formed between the semiconductor layer 131 of each transistor Tr and the SiN film 168-3.

The polyimide film 168-4 includes the polyimide film 171 formed on the SiN film 168-3 outside the opening P, and the polyimide film 172 formed on the side faces of the SiO₂ film 168-1, the hydrogen storage layer 168-2, and the SiN film 168-3 inside the opening P. According to the present embodiment, the side faces of the SiO₂ film 168-1, the hydrogen storage layer 168-2, and the SiN film 168-3 can be protected by the polyimide film 172. For example, it is possible to prevent H₂O molecules from entering the hydrogen storage layer 168-2 from a section of the hydrogen storage layer 168-2.

In the present embodiment, the SiN film 168-3 is formed by using source gas including hydrogen (H). For example, the SiN film 168-3 is formed by using monosilane (SiH₄) gas, nitrogen (N₂) gas, and ammonia (NH₃) gas. In this process, hydrogen radicals are generated due to such source gas. When the hydrogen radicals reach the semiconductor layer 131 of each transistor Tr, the characteristics of the semiconductor layer 131 may change, potentially degrading the performance of each transistor Tr. Since the hydrogen radicals are small in size, they can easily penetrate through SiO₂ films in the semiconductor device and reach the semiconductor layer 131. Furthermore, an IGZO layer can easily absorb hydrogen radicals, and when the IGZO layer absorbs hydrogen radicals, the characteristics of the IGZO layer become closer to those of a conductor layer rather than those of a semiconductor layer. As a result, when the semiconductor layer 131 is an IGZO layer, the threshold voltage of each transistor Tr shifts to the negative side.

Thus, the passivation insulator 168 of the present embodiment includes the hydrogen storage layer 168-2 below the SiN film 168-3. Accordingly, according to the present embodiment, hydrogen radicals can be stored by the hydrogen storage layer 168-2 and prevented from reaching the semiconductor layer 131. As a result, the characteristics of the semiconductor layer 131 can be excellently maintained. Note that such an effect can be achieved also when the semiconductor layer 131 is, for example, an oxide semiconductor layer other than an IGZO layer.

The upper face of the hydrogen storage layer 168-2 contacts the lower face of the SiN film 168-3 in the present embodiment, but does not necessarily need to contact the lower face of the SiN film 168-3. However, when the hydrogen storage layer 168-2 contacts the SiN film 168-3, hydrogen radicals due to the SiN film 168-3 can be easily stored by the hydrogen storage layer 168-2, and thus the hydrogen storage layer 168-2 desirably contacts the SiN film 168-3.

Typically, source gas including hydrogen (H) is used not only to form a SiN film but also to form a SiO₂ film. However, according to experiments, the amount of hydrogen radicals generated when a SiO₂ film is formed is typically smaller than the amount of hydrogen radicals generated when a SiN film is formed. Thus, the hydrogen storage layer 168-2 is desirably provided below the SiN film 168-3.

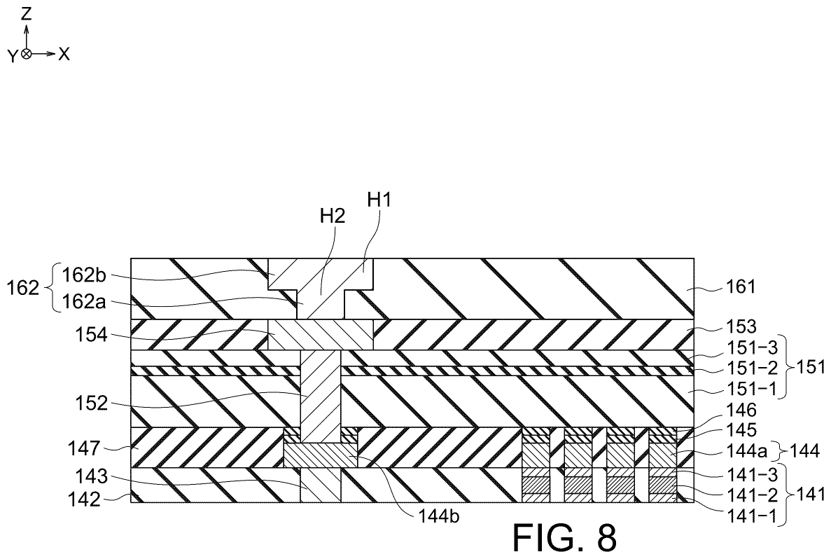

FIGS. 8 to 10 are cross-sectional views illustrating the method of manufacturing the semiconductor device of the first embodiment. FIGS. 8 to 10 illustrate processes of forming the structure illustrated in FIG. 7.

First, the interlayer dielectric 161 is formed on the interlayer dielectric 153 and the interconnect layer 154, and openings H1 and H2 are formed in the interlayer dielectric 161 (FIG. 8). The opening H2 is formed below the opening H1, and the upper face of the interconnect layer 154 is exposed in the opening H2. Subsequently, the interconnect layer 162 is formed in the openings H1 and H2 (FIG. 8). The via plug portion 162a is formed on the interconnect layer 154 in the opening H2, and the interconnect portion 162b is formed on the via plug portion 162a in the opening H1. The opening H1 corresponds to a via hole, and the opening H2 corresponds to an interconnect trench.

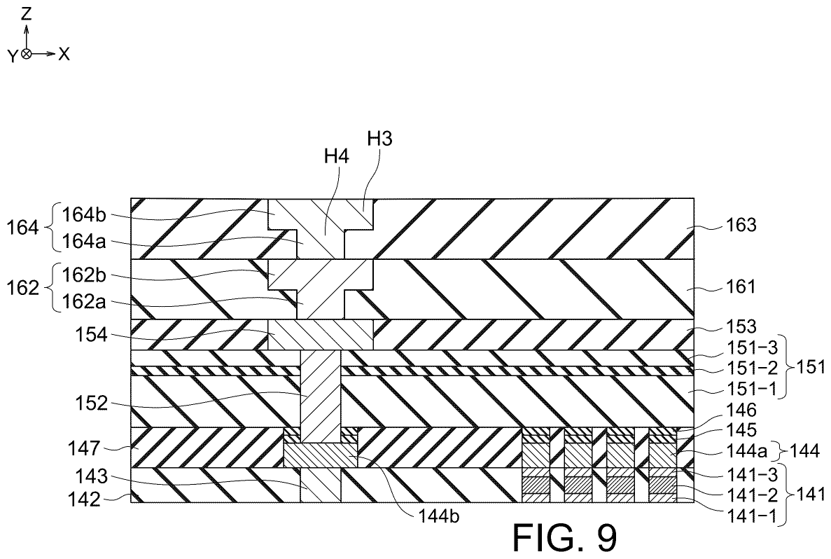

Subsequently, the interlayer dielectric 163 is formed on the interlayer dielectric 161 and the interconnect layer 162, and openings H3 and H4 are formed in the interlayer dielectric 163 (FIG. 9). The opening H4 is formed below the opening H3, and the upper face of the interconnect portion 162b is exposed in the opening H4. Subsequently, the interconnect layer 164 is formed in the openings H3 and H4 (FIG. 9). The via plug portion 164a is formed on the interconnect portion 162b in the opening H4, and the interconnect portion 164b is formed on the via plug portion 164a in the opening H3. The opening H3 corresponds to a via hole, and the opening H4 corresponds to an interconnect trench.

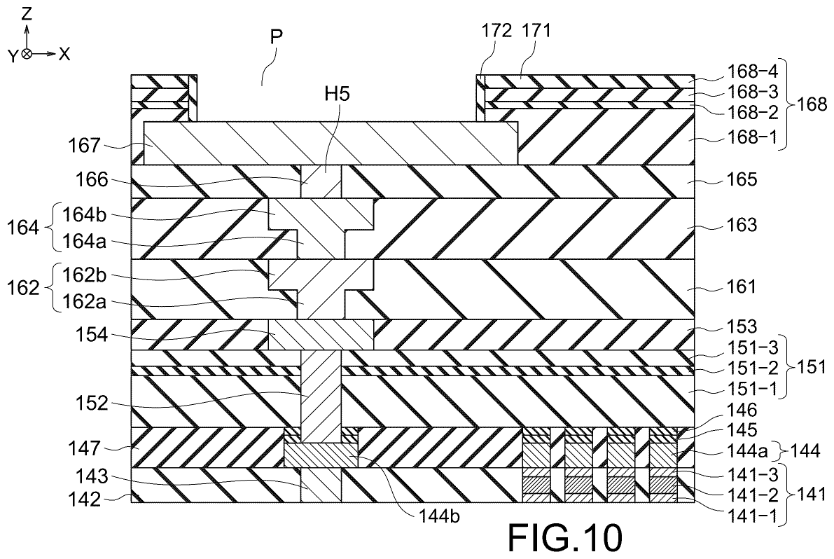

Subsequently, the interlayer dielectric 165 is formed on the interlayer dielectric 163 and the interconnect layer 164, and an opening H5 is formed in the interlayer dielectric 165 (FIG. 10). The upper face of the interconnect portion 164b is exposed in the opening H5. Subsequently, the via plug 166 is formed in the opening H5 (FIG. 10). The via plug 166 is formed on the interconnect portion 164b in the opening H5. The opening H5 corresponds to a via hole.

Subsequently, the bonding pad 167 is formed on the interlayer dielectric 165 and the via plug 166, and the SiO₂ film 168-1, the hydrogen storage layer 168-2, the SiN film 168-3, and the polyimide film 171 are sequentially formed on the interlayer dielectric 165 and the bonding pad 167 (FIG. 10). The SiN film 168-3 is formed by using, for example, the above-described source gas. The source gas is an example of first gas.

Subsequently, the opening P is formed in the polyimide film 171, the SiN film 168-3, the hydrogen storage layer 168-2, and the SiO₂ film 168-1 by lithography and reactive ion etching (RIE) (FIG. 10). As a result, the upper face of the bonding pad 167 is exposed in the opening P.

Subsequently, the polyimide film 172 is formed on the side faces of the SiO₂ film 168-1, the hydrogen storage layer 168-2, the SiN film 168-3, and the polyimide film 171 in the opening P (FIG. 10). As a result, the polyimide film 168-4 is formed so as to include the polyimide film 171 outside the opening P and the polyimide film 172 inside the opening P. Note that further details of the process of forming the polyimide film 172 will be described later. In this manner, the semiconductor device of the present embodiment is manufactured.

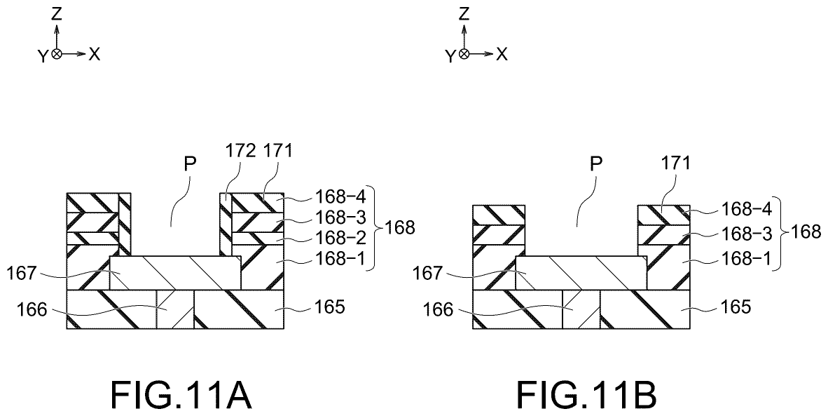

FIGS. 11A and 11B are cross-sectional views illustrating the structure of the semiconductor device of the first embodiment and the structure of a semiconductor device of a comparative example of the first embodiment.

FIG. 11A illustrates the bonding pad 167, the passivation insulator 168, and the like of the semiconductor device of the present embodiment. The passivation insulator 168 of the present embodiment includes constituent components described above with reference to FIG. 7. FIG. 11B illustrates the bonding pad 167, the passivation insulator 168, and the like of the semiconductor device of the comparative example. The passivation insulator 168 of the comparative example does not include the hydrogen storage layer 168-2 nor the polyimide film 172.

With the hydrogen storage layer 168-2, the present embodiment makes it possible to store hydrogen radicals with the hydrogen storage layer 168-2 and prevent the hydrogen radicals from reaching the semiconductor layer 131 of each transistor Tr. Moreover, with the polyimide film 172, the present embodiment makes it possible to protect the side faces of the SiO₂ film 168-1, the hydrogen storage layer 168-2, and the SiN film 168-3 with the polyimide film 172.

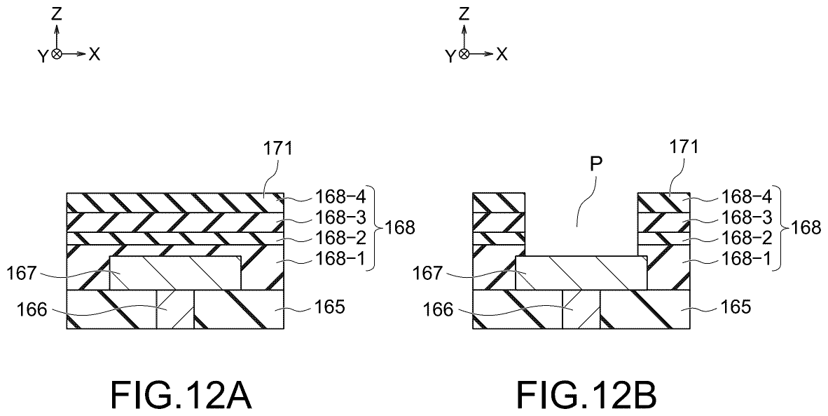

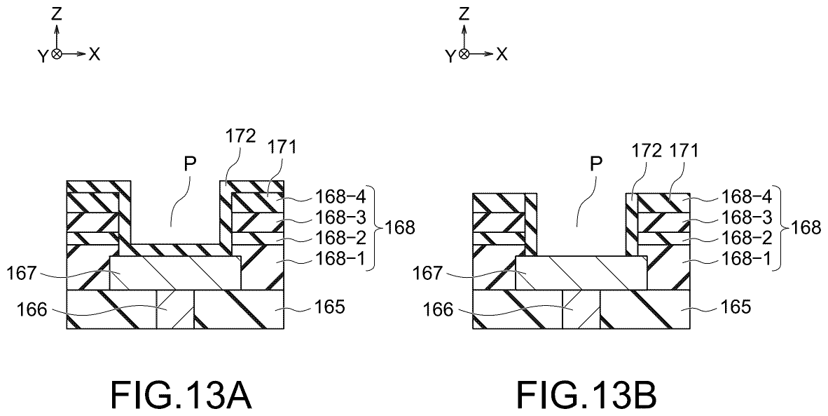

FIGS. 12A to 13B are cross-sectional views illustrating the method of manufacturing the semiconductor device of the first embodiment. FIGS. 12A to 13B illustrates processes of forming the structure illustrated in FIG. 11A.

First, the bonding pad 167 is formed on the interlayer dielectric 165 and the via plug 166 (FIG. 12A). Subsequently, the SiO₂ film 168-1, the hydrogen storage layer 168-2, the SiN film 168-3, and the polyimide film 171 are sequentially formed on the interlayer dielectric 165 and the bonding pad 167 (FIG. 12A).

Subsequently, the opening P is formed in the polyimide film 171, the SiN film 168-3, the hydrogen storage layer 168-2, and the SiO₂ film 168-1 by RIE (FIG. 12B). As a result, the upper face of the bonding pad 167 is exposed in the opening P.

Subsequently, the polyimide film 172 is formed on the bonding pad 167 and the polyimide film 171 (FIG. 13A). As a result, the polyimide film 172 is formed on the upper face of the bonding pad 167 and the side faces of the SiO₂ film 168-1, the hydrogen storage layer 168-2, the SiN film 168-3, and the polyimide film 171 inside the opening P and on the upper face of the polyimide film 171 outside the opening P.

Subsequently, the polyimide film 172 is processed by RIE (FIG. 13B). As a result, the polyimide film 172 is removed from the upper face of the bonding pad 167, and the upper face of the bonding pad 167 is exposed. In addition, the polyimide film 172 is removed from the upper face of the polyimide film 171, and the upper face of the polyimide film 171 is exposed. In this process, the polyimide film 172 on the upper face of the polyimide film 171 may be reduced in thickness instead of being completely removed. In addition, the polyimide film 171 may be reduced in thickness when the polyimide film 172 is removed from the upper face of the polyimide film 171.

As described above, the passivation insulator 168 of the present embodiment includes the hydrogen storage layer 168-2 below the SiN film 168-3. Thus, the present embodiment makes it possible to excellently maintain the characteristics of the semiconductor layer 131 of each transistor Tr. For example, it is possible to store hydrogen radicals with the hydrogen storage layer 168-2 and prevent the hydrogen radicals from reaching the semiconductor layer 131. This makes it possible to prevent change in the characteristics of the semiconductor layer 131 due to the hydrogen radicals, thereby preventing degradation of the performance of each transistor Tr.

Note that the hydrogen storage layer 168-2 may be formed of an element or material different from the above-described elements and materials. For example, the hydrogen storage layer 168-2 may include a metal element other than Ti, Ta, Hf, La, and Zr.

Moreover, the semiconductor device of the present embodiment may include a hydrogen storage layer and a SiN film that are different from the hydrogen storage layer 168-2 and the SiN film 168-3. In this case, the semiconductor device of the present embodiment may include the hydrogen storage layer 168-2 and the SiN film 168-3 as well as the other hydrogen storage layer and SiN film. Examples of such hydrogen storage layer and SiN film will be described below in a second embodiment.

### Second Embodiment

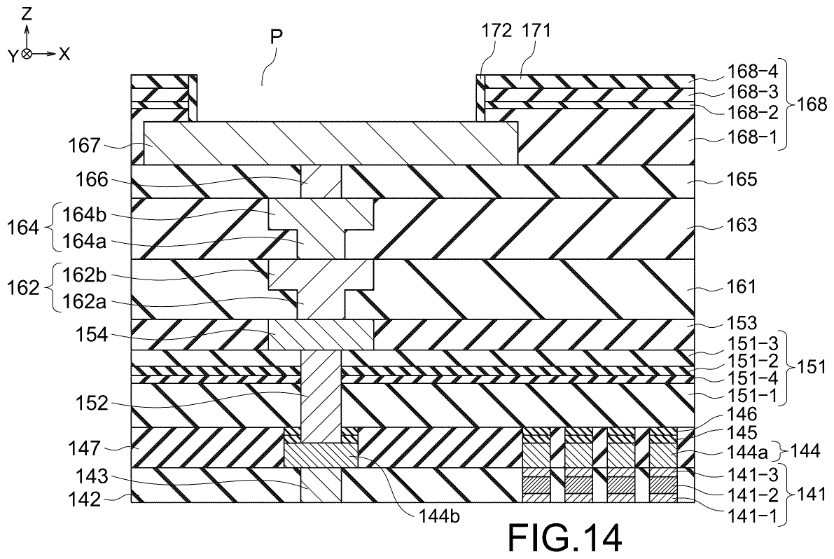

FIG. 14 is a cross-sectional view illustrating the structure of a semiconductor device of the second embodiment.

The semiconductor device of the present embodiment (FIG. 14) includes a hydrogen storage layer 151-4 in the interlayer dielectric 151 in addition to the constituent components illustrated in FIGS. 1 and 7. The hydrogen storage layer 151-4 is provided between the SiO₂ film 151-1 and the SiN film 151-2, and the upper face of the hydrogen storage layer 151-4 contacts the lower face of the SiN film 151-2. The hydrogen storage layer 151-4 is an example of the first layer. The SiN film 151-2 is an example of the first film.

The semiconductor device of the present embodiment includes the hydrogen storage layer 168-2 between the SiO₂ film 168-1 and the SiN film 168-3 and includes the hydrogen storage layer 151-4 between the SiO₂ film 151-1 and the SiN film 151-2. The SiN film 168-3 and the hydrogen storage layer 168-2 are examples of an upper film and an upper layer, respectively. The SiN film 151-2 and the hydrogen storage layer 151-4 are examples of a lower film and a lower layer, respectively.

Similarly to the hydrogen storage layer 168-2, the hydrogen storage layer 151-4 is a layer capable of storing hydrogen (H). The hydrogen storage layer 151-4 includes, for example, a metal element. The metal element is, for example, Ti, Ta, Hf, La, or Zr. The hydrogen storage layer 151-4 includes, for example, a metal element and includes oxygen or nitrogen. Examples of such a hydrogen storage layer 151-4 include a metal oxide film and a metal nitride film. The hydrogen storage layer 151-4 is, for example, an insulator. The thickness of the hydrogen storage layer 151-4 is, for example, equal to or smaller than 20 nm. It is possible to enhance the H storage capability of the hydrogen storage layer 151-4 by increasing the thickness of the hydrogen storage layer 151-4, and it is possible to prevent excessive increase in the thickness of the interlayer dielectric 151 by decreasing the thickness of the hydrogen storage layer 151-4. For example, it is possible to decrease the aspect ratio of the via plug 152 by decreasing the thickness of the interlayer dielectric 151.

The SiN film 151-2 is formed on the hydrogen storage layer 151-4. The density of the SiN film 151-2 is, for example, higher than 2.7 g/cm³ but may be lower than 2.7 g/cm³. The density of the SiN film 151-2 can be adjusted, for example, by changing temperature and source gas for forming the SiN film 151-2. The SiN film 151-2 is formed as, for example, a hydrogen barrier film for blocking hydrogen radicals. In this case, the density of the SiN film 151-2 is preferably high, and preferably higher than 2.7 g/cm³, for example.

The SiO₂ film 151-1, the hydrogen storage layer 151-4, and the SiN film 151-2 each have a plate shape spreading along the XY plane above the semiconductor layer 131 (refer to FIG. 2) of each transistor Tr. Accordingly, the semiconductor layer 131 of each transistor Tr of the present embodiment is disposed so as to overlap the SiO₂ film 151-1, the hydrogen storage layer 151-4, and the SiN film 151-2 in a plan view. The hydrogen storage layer 151-4 is formed between the semiconductor layer 131 of each transistor Tr and the SiN film 151-2.

In the present embodiment, the SiN film 151-2 is formed by using source gas including hydrogen (H). The SiN film 151-2 is formed by using SiH₄ gas, N₂ gas, and NH₃ gas, for example. In this process, hydrogen radicals are generated due to such source gas. When the hydrogen radicals reach the semiconductor layer 131 of each transistor Tr, the characteristics of the semiconductor layer 131 may change, potentially degrading the performance of each transistor Tr.

Thus, the interlayer dielectric 151 of the present embodiment includes the hydrogen storage layer 151-4 below the SiN film 151-2. Accordingly, the present embodiment makes it possible to store hydrogen radicals with the hydrogen storage layer 151-4 and prevent the hydrogen radicals from reaching the semiconductor layer 131 in the same manner with the hydrogen storage layer 168-2. This makes it possible to excellently maintain the characteristics of the semiconductor layer 131.

Note that the SiN film 151-2 is formed as, for example, a hydrogen barrier film for blocking hydrogen radicals as described above. Accordingly, hydrogen radicals generated above the SiN film 151-2 are blocked by the SiN film 151-2. However, hydrogen radicals generated when the SiN film 151-2 is formed are typically not blocked by the SiN film 151-2. Thus, the interlayer dielectric 151 of the present embodiment includes the hydrogen storage layer 151-4 below the SiN film 151-2 to handle such hydrogen radicals.

In the following, the hydrogen storage layer 151-4 and the SiN film 151-2 is compared with the hydrogen storage layer 168-2 and the SiN film 168-3.

In a case where the SiN film 151-2 is formed as a hydrogen barrier film, the density of the SiN film 151-2 is preferably high. Accordingly, in the present embodiment, the density of the SiN film 151-2 is preferably higher than the density of the SiN film 168-3. For example, the density of the SiN film 151-2 may be set to be higher than 2.7 g/cm³, and the density of the SiN film 168-3 may be set to be lower than 2.7 g/cm³.

The hydrogen storage layer 151-4 is positioned below the hydrogen storage layer 168-2 and formed before the hydrogen storage layer 168-2 is formed. Accordingly, the hydrogen storage layer 151-4 typically stores a larger number of H atoms than the hydrogen storage layer 168-2, and the concentration of H atoms in the hydrogen storage layer 151-4 becomes higher than that in the hydrogen storage layer 168-2. However, the concentration of H atoms in the hydrogen storage layer 151-4 may become lower than that in the hydrogen storage layer 168-2, depending on the thicknesses of the SiN films 151-2 and 168-3 and temperature for forming the SiN films 151-2 and 168-3. In this manner, the concentration of H atoms in the hydrogen storage layers 151-4 and 168-3 is potentially affected by factors other than the positional relation between the hydrogen storage layers 151-4 and 168-3.

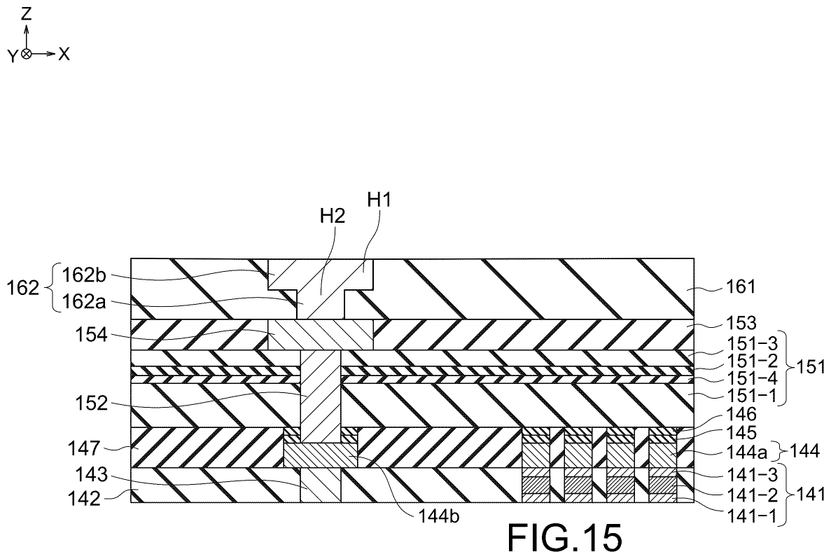

FIG. 15 is a cross-sectional view illustrating a method of manufacturing the semiconductor device of the second embodiment.

FIG. 15 illustrates a section corresponding to FIG. 8. In the present embodiment, when the interlayer dielectric 151 is to be formed, the SiO₂ film 151-1, the hydrogen storage layer 151-4, the SiN film 151-2, and the SiO₂ film 151-3 are sequentially formed on the insulator 146 and the interlayer dielectric 147 (refer to FIG. 6). As a result, when the process in FIG. 15 is started in place of the process in FIG. 8, the hydrogen storage layer 151-4 is already provided in the interlayer dielectric 151.

As described above, the interlayer dielectric 151 of the present embodiment includes the hydrogen storage layer 151-4 below the SiN film 151-2. Accordingly, similarly to the first embodiment, the present embodiment makes it possible to excellently maintain the characteristics of the semiconductor layer 131 of each transistor Tr.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

1. A semiconductor device comprising:
an oxide semiconductor layer including a metal element and oxygen, the oxide semiconductor layer being a channel of a transistor;
a first film provided above the oxide semiconductor layer, and including silicon and nitrogen; and
a hydrogen storage layer provided between the oxide semiconductor layer and the first film.

2. The device of claim 1, wherein the metal element is indium (In), gallium (Ga), zinc (Zn), tin (Sn) or aluminum (Al).

3. The device of claim 1, wherein the first film is an insulator.

4. The device of claim 1, wherein the first film has a density higher than 2.7 g/cm³.

5. The device of claim 1, wherein the hydrogen storage layer is an insulator.

6. The device of claim 1, wherein the hydrogen storage layer includes titanium (Ti), tantalum (Ta), hafnium (Hf), lanthanum (La) or zirconium (Zr).

7. The device of claim 1, wherein the hydrogen storage layer includes a metal element, and includes oxygen or nitrogen.

8. The device of claim 1, further comprising:
a bonding pad; and
a first insulator including an opening on the bonding pad,
wherein the first film is included in the first insulator.

9. The device of claim 8, wherein the hydrogen storage layer is included in the first insulator.

10. The device of claim 8, wherein the first insulator further includes a second film provided on a side face of the first film inside the opening.

11. The device of claim 10, wherein the second film is further provided on the first film outside the opening.

12. The device of claim 10, wherein the second film is an organic insulator.

13. The device of claim 1, further comprising:
a bonding pad; and
a first insulator including an opening on the bonding pad,
wherein the first film is provided below the first insulator.

14. The device of claim 1, further comprising:
a bonding pad; and
a first insulator including an opening on the bonding pad,
wherein
the device includes, as the first film, an upper film included in the first insulator, and a lower film provided below the first insulator, and
the device includes, as the hydrogen storage layer, an upper layer provided between the upper film and the lower film, and a lower layer provided between the lower film and the oxide semiconductor layer.

15. The device of claim 14, wherein a density of the lower film is higher than a density of the upper film.

16. The device of claim 14, wherein hydrogen concentration in the lower layer is higher than hydrogen concentration in the upper layer.

17. The device of claim 14, wherein hydrogen concentration in the lower layer is lower than hydrogen concentration in the upper layer.

18. A semiconductor device comprising:
an oxide semiconductor layer including a metal element and oxygen, the oxide semiconductor layer being a channel of a transistor;
a first film provided above the oxide semiconductor layer, and including silicon and nitrogen; and
a first layer provided between the oxide semiconductor layer and the first film, and including titanium (Ti), tantalum (Ta), hafnium (Hf), lanthanum (La) or zirconium (Zr).

19. A method of manufacturing a semiconductor device, comprising:
forming an oxide semiconductor layer including a metal element and oxygen, the oxide semiconductor layer being a channel of a transistor;
forming a first layer above the oxide semiconductor layer; and
forming, above the first layer, a first film including silicon and nitrogen by using first gas including hydrogen (H),
wherein the first layer is a hydrogen storage layer, or includes titanium (Ti), tantalum (Ta), hafnium (Hf), lanthanum (La) or zirconium (Zr).

20. The method of claim 19, wherein the first gas is monosilane (SiH₄) gas or ammonia (NH₃) gas.
